(19) United States
(12) Patent Application Publication
(10) Pub. No.: US 2022/0225549 A1
(43) Pub. Date: Jul. 14, 2022

(54) SEMICONDUCTOR COMPONENT ON A HEAT PIPE

(71) Applicant: Siemens Healthcare GmbH, München (DE)

(72) Inventor: Uwe Waltrich, Forchheim (DE)

(21) Appl. No.: 17/611,132

(22) PCT Filed: Apr. 16, 2020
(86) PCT No.: PCT/EP2020/060663

§ 371 Date: Nov. 12, 2021

(30) Foreign Application Priority Data
May 13, 2019 (DE) 10 2019 206 896.0

(51) Int. Cl. H05K 7/20; H01L 23/427; B64D 33/08

(52) U.S. Cl. CPC H05K 7/20936; B64D 33/08; H01L 23/427

(57) ABSTRACT

The invention relates to a method for joining a power semiconductor component (1.1) to a heat pipe (2), wherein, during joining, the external pressure (p2) acting on the heat pipe (2) is changed proportionally to the internal pressure (p1) of the heat pipe (2), which internal pressure changes under heat during joining. The invention also relates to a device for carrying out the method, a power module, a converter and a vehicle.

This application is the National Stage of International Application No. PCT/EP2020/060663, filed Apr. 16, 2020, which claims the benefit of German Patent Application No. DE 10 2019 206 896.0, filed May 13, 2019. The entire contents of these documents are hereby incorporated herein by reference.

### FIELD

The present embodiments relate to joining a power semiconductor component to a heat pipe.

### BACKGROUND

Since the power losses to be dissipated in power modules are produced only in a point-like manner in the power semiconductor component (e.g., chip area ˜1 cm²), the lateral heat conduction (e.g., “heat spreading”) within the power module plays a critical role in order to minimize the thermal resistance of the semiconductor or of the module for cooling. The higher the lateral heat conduction with a constant vertical heat conduction, the better is the utilization of the cooling area available.

A very effective way of transporting heat laterally is represented by the use of heat pipes (e.g., heat pipes, vapor chamber/oscillating heat pipes). Heat pipes of this type may be hollow solid bodies (e.g., cylinders or pressure-flattened cylinders) that are filled with a defined quantity of a fluid and closed in a gas-tight manner. Using the phase transition of the fluid, considerably higher thermal conductivities are achieved than in classic materials and electric conductors in power electronics.

If the entire heat pipe is heated intensively above the boiling point of the fluid used (e.g., in a soldering process), the whole of the fluid evaporates. This increases the internal pressure of the heat pipe, with the result that it is possible for deformation or explosion of the heat pipe to occur. For example, in the case of flat heat pipes (e.g., vapor chambers), joining methods that are subjected to temperature are therefore not possible because of the geometry.

Therefore, heat pipes of this type are normally attached to the heat source by adhesive or pressure connections, the boiling point of the fluid not being exceeded. The thermal and the electrical conductivity between a heat source and a heat pipe is thus not optimal according to the prior art.

The attachment of power semiconductor components to heat pipes by conventional joining methods of power electronics (e.g., soldering, silver sintering) that permit a high thermal conductivity between semiconductor and heat pipe is therefore not possible, as explained above.

In the joining method of silver sintering under pressure, a further problem is added. In addition to the joining temperature (>200° C.), a mechanical pressure on the joining layer is to be provided. This is applied via pressure plungers. This is not possible when joining to heat pipes, since the heat pipe will be deformed and destroyed as a result.

Lateral thermal conduction of classic power modules is mainly achieved by the copper metallizations of the ceramic insulating substrates used. These have a maximum lateral thermal conductivity of less than 400 W/mK. In addition, the available layer thicknesses of the copper metallizations of such substrates are less than 1 mm, which likewise limits the lateral thermal conduction. This leads to the use of large heat sinks with extremely long and heavy cooling fins.

The attachment of power semiconductor components to heat pipes using conventional joining methods of power electronics (e.g., soldering, silver sintering) that permit high thermal conductivity between semiconductor and heat pipe has not been possible until now.

In manufacturing technology, joining is one of the main manufacturing groups. During joining, two or more solid bodies having a geometrically determined shape are connected (e.g., joined) permanently. Occasionally, use is additionally made of a “dimensionless material”, the shape of which is not defined. This includes, for example, adhesive. The most important joining techniques include, for example, welding, soldering, and adhesive bonding. Further important methods are riveting, clinching, and screwing.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a thermal conductivity between power semiconductor components and a heat pipe in a power module is improved.

An integral electrical attachment of power semiconductor components to heat pipes being implemented by joining in a pressure chamber is provided.

During soldering, the set chamber overpressure counteracts a vapor pressure in the heat pipe at elevated joining temperature and, as a result, prevents deformation or bursting of the heat pipe. The vapor pressure of water at conventional soldering temperatures (e.g., 200° C. 220° C.) lies in the range from 20 to 30 bar. This is a usual pressure that, for example, may be achieved in autoclaves. An autoclave is a pressure container that may be closed in a gas-tight manner, which is used for the thermal treatment of substances in the positive pressure range.

During sintering (e.g., Ag sintering), the overpressure in the pressure chamber may also be used directly for the actual joining method if this method requires a mechanical pressure on the joining location (e.g., during Ag sintering). The pressure difference required for this purpose may be provided, for example, via gas-tight films or pockets, in which the component (e.g., joining partners) to be joined are fixed and in which a constant pressure may be maintained.

The material of the pocket may be semi-permeable in order that the organic solvents of the sintering paste may evaporate out during the sintering. In addition, the material may be as flexible and crack-resistant as possible in order to match the fine edge structures of the chip upper side in order to produce a uniform pressure on the sintered layer. The chamber overpressure may be used in the same process step to bend the heat pipe into a specific shape using a tool or to produce impressions.

The present embodiments provide a process for the integral, electrically, and thermally conductive connection of a power semiconductor component to a heat pipe. One advantage is that heat pipes that are already closed and therefore obtainable on the market may be used. Classic soldering of an unenclosed and unfilled heat pipe is alternatively possible. However, this necessitates subsequent welding/adhesive bonding (e.g., not a clean room process) of the heat pipe equipped with semiconductors. Silver sintering may not be possible, however, since the mechanical pressure of the plunger may destroy the heat pipe.

High temperature-resistant joining methods for the attachment of heat pipes may be used.

A significantly improved thermal and electrical contact resistance of the connection between heat source (e.g., power semiconductor component) and heat pipe as compared with pressed or adhesively bonded connections may be provided.

The laterally thermally conductive layer directly underneath the heat source improves the thermal resistance.

A saving of thick copper layers in the insulating substrates leads to a reduction in weight of the power module.

The present embodiments include a method for joining a power semiconductor component to a heat pipe, where, during the joining, the external pressure acting on the heat pipe is changed proportionally to the internal pressure of the heat pipe. The internal pressure changes as a result of the action of heat during the joining.

In a development, the external pressure at the start of the joining is greater than the internal pressure.

In a development, the joining is soldering or sintering, where during sintering, the heat pipe and the power semiconductor component are located in a pocket that presses the power semiconductor component onto the heat pipe by increasing the external pressure.

In a development, during the sintering, the heat pipe and the power semiconductor component may be located under a plastic film that presses the power semiconductor element onto the heat pipe by increasing the external pressure.

The present embodiments also include a device for joining a power semiconductor component to a heat pipe. The device includes a pressure chamber in which the method of the present embodiments is carried out.

The present embodiments include a power module having at least one power semiconductor component and at least one heat pipe that are joined by a method of the present embodiments.

In addition, the present embodiments include a converter (e.g., an inverter) having a plurality of power modules according to the present embodiments.

Inverter designates a converter that generates an alternating voltage changed in frequency and amplitude from an alternating voltage or direct voltage. Frequently, inverters are configured as AC/DC-DC/AC inverters or DC/AC inverters, where an AC output voltage is generated from an AC input voltage or an input DC voltage via a DC voltage intermediate circuit and clocked semiconductors.

The present embodiments include a vehicle having a converter according to the present embodiments for an electric or hybrid-electric drive.

A vehicle may be any type of locomotion or transport device, be it manned or unmanned. An aircraft is a flying vehicle.

In a development, the vehicle may be an aircraft (e.g., an airplane).

In a development, the airplane has an electric motor supplied with electrical energy by the converter and a propeller that may be set rotating by the electric motor.

Further, special features and advantages of the present embodiments will be illustrated by the following explanations of exemplary embodiments with reference to schematic drawings.

### BRIEF DESCRIPTION OF THE DRAWINGS

FIG. 1 shows a side view of a power module according to the prior art;

FIG. 2 shows a view of one embodiment of a pressure chamber for soldering;

FIG. 3 shows a view of one embodiment of a pressure chamber for sintering with a pocket;

FIG. 4 shows a view of one embodiment of a pressure chamber for sintering with a plastic film;

FIG. 5 shows a block diagram of one embodiment of a converter having a power module; and

FIG. 6 shows one embodiment of an aircraft having an electric thrust-generating unit.

### DETAILED DESCRIPTION

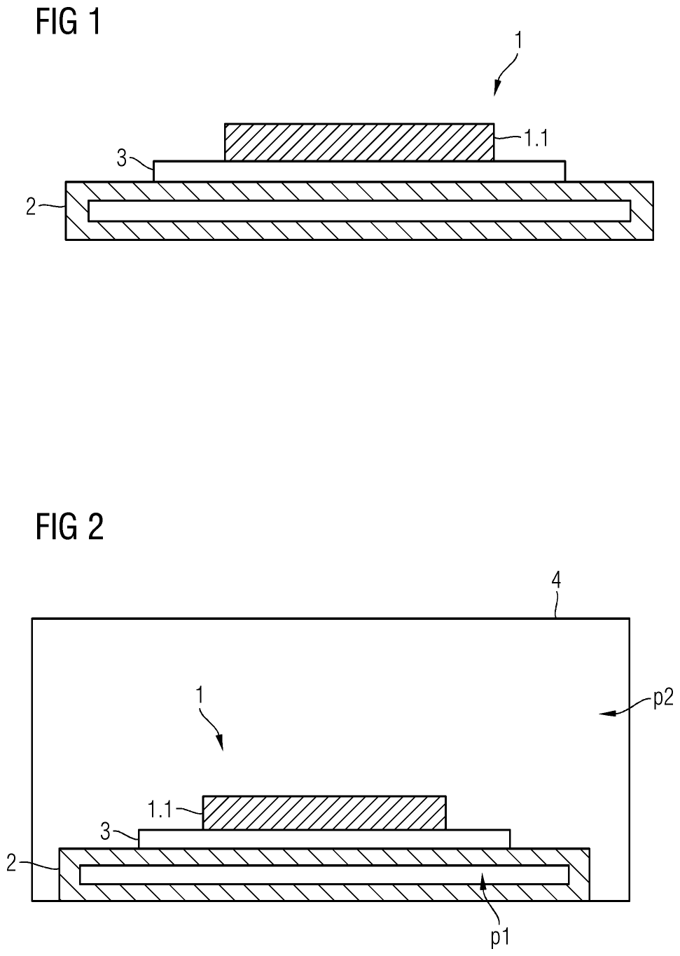

FIG. 1 shows a side view of parts of a power module 1 of a converter according to the prior art. A plurality of power semiconductor components 1.1 (only one is visible) are joined to a heat pipe 2 with the aid of an integral connection 3 (e.g., adhesive). The heat pipe 2 is used for effective heat dissipation of a power loss of the power semiconductor components 1.1. The heat pipe 2 is, for example, filled with water.

FIG. 2 shows a view of a device for soldering power semiconductor components 1.1 of a power module 1 to a water-filled heat pipe 2. The integral connection 3 is produced by a solder. In order that an internal pressure p1 in an interior of the heat pipe 2 during soldering does not cause the heat pipe 2 to burst, the soldering operation is carried out in a pressure chamber 4 that builds up an external pressure p2. The external pressure p2 is automatically adjusted such that the internal pressure p1 is always approximately equal to the external pressure p2.

This may be done, for example, by the internal pressure p1 in the heat pipe 2 being estimated by a temperature measurement on the heat pipe 2 and, for example, the external pressure p2 being increased in accordance with a recorded and stored table of the vapor pressure of water.

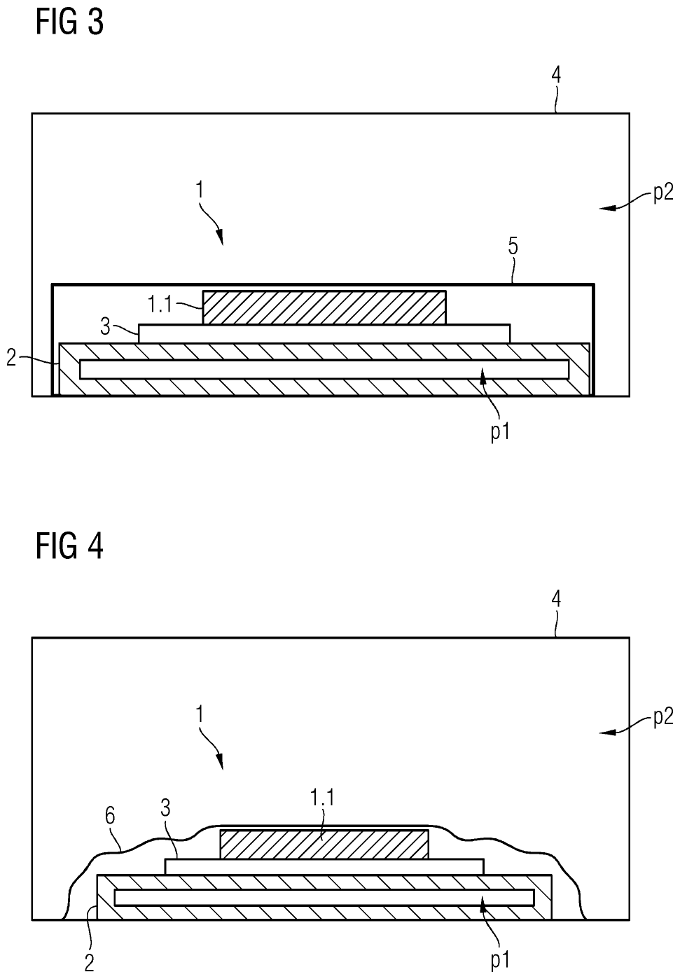

FIG. 3 shows a view of one embodiment of a device for sintering power semiconductor components 1.1 of a power module 1 onto a water-filled heat pipe 2. The integral connection 3 is produced by fine-grained ceramic or metallic materials. In order to apply the necessary pressure for sintering to the power semiconductor components 1.1, the power module 1 is arranged in a pocket 5. By increasing the external pressure p2, the fine-grained ceramic or metallic substances are melted.

In order that the internal pressure p1 in the interior of the heat pipe 2 during the soldering does not cause the heat pipe 2 to burst, the soldering operation is carried out in a pressure chamber 4 that builds up an external pressure p2. The external pressure p2 is automatically adjusted such that the internal pressure p1 is always approximately equal to the external pressure p2.

This may be done, for example, by the internal pressure p1 in the heat pipe 2 being estimated by a temperature measurement on the heat pipe 2 and, for example, the external pressure p2 being increased in accordance with a recorded and stored table of the vapor pressure of water.

FIG. 4 shows a view of an alternative device to FIG. 3 for sintering power semiconductor components 1.1 of a power module 1 onto a water-filled heat pipe 2. The integral connection 3 is produced by fine-grained ceramic or metallic materials. In order to apply the necessary pressure for sintering to the power semiconductor components 1.1, the power module 1 is enclosed by a plastic film 6. By increasing the external pressure p2, the plastic film 6 is pressed onto the power semiconductor components 1.1, and the fine-grained ceramic or metallic substances are melted.

In order that the internal pressure p1 in the interior of the heat pipe 2 during the soldering does not cause the heat pipe 2 to burst, the soldering operation is carried out in a pressure chamber 4 that builds up an external pressure p2. The external pressure p2 is automatically adjusted such that the internal pressure p1 is approximately equal to the external pressure p2.

This may be done, for example, by the internal pressure p1 in the heat pipe 2 being estimated by a temperature measurement on the heat pipe 2 and, for example, the external pressure p2 being increased in accordance with a recorded and stored table of the vapor pressure of water.

FIG. 5 shows a block diagram of one embodiment of a converter 7.3 (e.g., an inverter) having a power module 1 according to the illustrations of FIG. 2 to FIG. 4, joined according to the present embodiments.

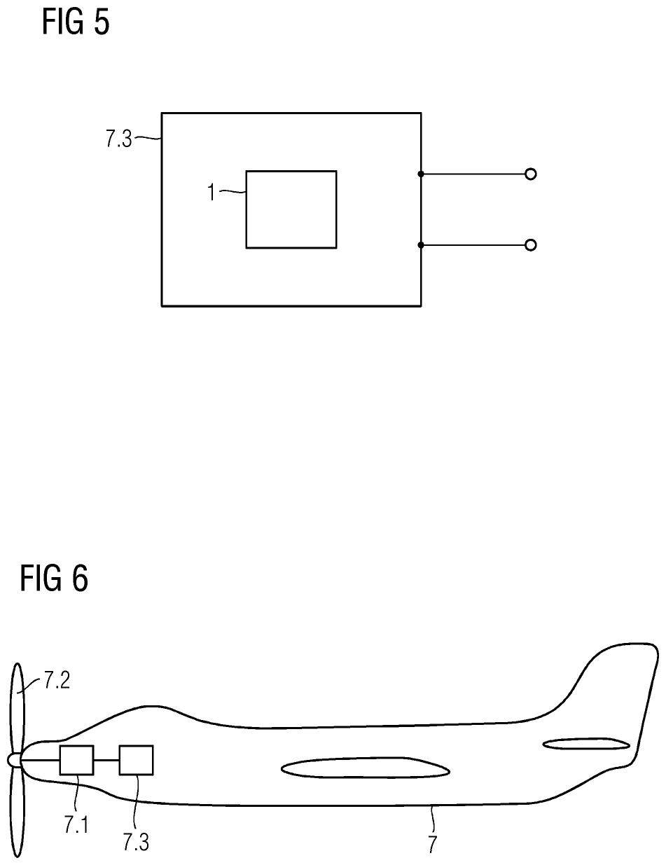

FIG. 6 shows one embodiment of an electric or hybrid-electric aircraft 7 (e.g., an airplane) having a converter 7.3 according to FIG. 5, which supplies an electric motor 7.1 with electrical energy. The electric motor 7.1 drives a propeller 7.2. Both are part of an electric thrust-generating unit.

Although the invention has been illustrated and described in more detail via the exemplary embodiments, the invention is not restricted by the examples disclosed, and other variations may be derived therefrom by those skilled in the art without departing from the protective scope of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for joining a power semiconductor component to a heat pipe, the method comprising:
joining the power semiconductor component to the heat pipe, the joining comprising changing an external pressure acting on the heat pipe proportionally to an internal pressure of the heat pipe, the internal pressure changing as a result of an action of heat during the joining.

2. The method of claim 1, wherein the external pressure at a start of the joining is greater than the internal pressure.

3. The method of claim 1, wherein the joining comprises soldering.

4. The method of claim 1, wherein the joining comprises sintering, and
wherein the heat pipe and the power semiconductor component are located in a pocket that presses the power semiconductor component onto the heat pipe when the external pressure is increased.

5. The method of claim 1, wherein the joining comprises sintering, and
wherein the heat pipe and the power semiconductor component are located under a plastic film that presses the power semiconductor component onto the heat pipe when the external pressure is increased.

6. A device for joining a power semiconductor component to a heat pipe, the device comprising:
a pressure chamber, in which the power semiconductor component is joinable to the heat pipe, the pressure chamber being configured to change an external pressure acting on the heat pipe proportionally to an internal pressure of the heat pipe, the internal pressure changing as a result of an action of heat during the join.

7. A power module comprising:
at least one power semiconductor component; and
at least one heat pipe,
wherein the at least one power semiconductor component and the at least one heat pipe are joined by a change of an external pressure acting on the heat pipe proportionally to an internal pressure of the heat pipe, the internal pressure changing as a result of heat during the join.

8. A converter comprising:
a plurality of power modules, a power module of the plurality of power modules comprising:
at least one power semiconductor component; and
at least one heat pipe,
wherein the at least one power semiconductor component and the at least one heat pipe are joined by a change of an external pressure acting on the heat pipe proportionally to an internal pressure of the heat pipe, the internal pressure changing as a result of heat during the join.

9. The converter of claim 8, wherein the converter is an inverter.

10. A vehicle comprising:
a converter for an electric or hybrid-electric drive, the converter comprising:
a plurality of power modules, a power module of the plurality of power modules comprising:
at least one power semiconductor component; and
at least one heat pipe,
wherein the at least one power semiconductor component and the at least one heat pipe are joined by a change of an external pressure acting on the heat pipe proportionally to an internal pressure of the heat pipe, the internal pressure changing as a result of heat during the join.

11. The vehicle of claim 10, wherein the vehicle is an aircraft.

12. The vehicle of claim 11, wherein the aircraft is an airplane.

13. The vehicle of claim 12, further comprising:
an electric motor supplied with electrical energy by the converter; and
a propeller set rotating rotatable by the electric motor.

14. The method of claim 2, wherein the joining comprises soldering.

15. The method of claim 2, wherein the joining comprises sintering, and
wherein the heat pipe and the power semiconductor component are located in a pocket that presses the power semiconductor component onto the heat pipe when the external pressure is increased.

16. The method of claim 2, wherein the joining comprises sintering, and
wherein the heat pipe and the power semiconductor component are located under a plastic film that presses the power semiconductor component onto the heat pipe when the external pressure is increased.
